(19) United States
(12) Patent Application Publication
(10) Pub. No.: US 2023/0207600 A1
(43) Pub. Date: Jun. 29, 2023

(54) SOLID-STATE IMAGE PICKUP ELEMENT AND ELECTRONIC DEVICE

(71) Applicant: Sharp Semiconductor Innovation Corporation, Tenri City (JP)

(72) Inventor: Hirokazu TANAKA, Tenri City (JP)

(21) Appl. No.: 17/993,912

(22) Filed: Nov. 24, 2022

(30) Foreign Application Priority Data
Dec. 28, 2021 (JP) 2021-214729

(51) Int. Cl. H01L 27/146

(52) U.S. Cl. CPC H01L 27/14636; H01L 27/14632; H01L 27/14609; H01L 27/14605

(57) ABSTRACT

A solid-state image pickup element comprises a pixel substrate having a pixel array; a logic substrate having a logic circuit that relates to the pixel array, and stacked on the pixel substrate; and a joint portion joined in such a manner that uppermost-layer wires of the respective pixel substrate and logic substrate face each other, wherein the logic circuit has a first terminal and a second terminal that are nodes identical to each other, the node of the first terminal and the node of the second terminal are nodes that are used for a circuit operation on only the logic substrate, the joint portion includes a first wire connecting the first terminal to the pixel substrate, and a second wire connecting the second terminal to the pixel substrate, and the pixel substrate includes a first connection wire connecting the first wire and e second wire together.

### CROSS-REFERENCE TO RELATED APPLICATION

The present application claims priority from Japanese Application JP2021-214729, the content of which is hereby incorporated by reference into this application.

### BACKGROUND

### Field

One aspect of the disclosure relates to a solid-state image pickup element having a matrix of unit pixels including an active element that convert, into an electric signal, a signal charge that has undergone photoelectric conversion by a photoelectric-conversion element, and that outputs the converted signal charge, and the aspect relates to an electronic device that includes the solid-state image pickup element. In particular, the aspect relates to a solid-state image pickup element that includes a plurality of stacked substrates and to an electronic device that includes the solid-state image pickup element.

### Description of the Related Art

Known solid-state image pickup elements include a charge-transfer type, typified by a charge coupled device (CCD) image sensor, and an X-Y address type, typified by a complementary metal oxide semiconductor (CMOS) image sensor. These solid-state image pickup elements are widely used in, but not limited to, digital still cameras and digital video cameras.

CMOS image sensors have been widely used recently particularly in mobile apparatuses (e.g., camera-equipped mobile phone), vehicle-mounted cameras, surveillance cameras, and factory-automation (FA) apparatuses.

An X-Y address solid-state image pickup element, typified by a CMOS image sensor, is composed of the following: a pixel region for taking out, as an electric signal, a signal charge received and undergone photoelectric conversion; and a peripheral-circuit region for driving and reading a pixel and subjecting the pixel to signal processing to output the pixel.

The pixel region includes a photo diode, which serves as a photoelectric-conversion element, and a plurality of pixel transistors are disposed in rows and columns two-dimensionally as a unit pixel. Incident light undergoes photoelectric conversion in the photo diode formed on a substrate (e.g., a silicon substrate) and accumulates as a signal charge. The plurality of pixel transistors consist of three transistors that respectively perform transfer, reset and amplification of the signal charge or consist of four transistors: three of them are the foregoing and an additional selection transistor that selects a pixel address that is to be read.

One or more metal wire layers are disposed over the substrate. Known pixel structures (see for instance, Japanese Patent No. 3759435 include a front-surface irradiation type that takes in incident light through the wire layers, which corresponds to a front surface, and a back-surface irradiation type that takes in incident light through the substrate's surface, which is opposite the wire layers. Some of such substrates have their light receiving surfaces over which a micro lens for increasing light reception sensitivity, a color filter for obtaining color information, or other things are provided.

The foregoing peripheral-circuit region includes various logic circuits, including a pixel driving circuit, and a signal processing circuit, typified by an AD conversion circuit. A high-speed clock signal tends to have been used in such logic circuits recently in order to achieve high-speed data transfer.

A known solid-state image pickup element (see for instance, Japanese Patent No. 5773379) is composed of a stack of a pixel substrate provided with a pixel region, and a logic substrate provided with a peripheral-circuit region. The stacked pixel substrate and logic substrate are electrically connected together via a joint of conductive material coupling the uppermost metals on both substrates together or via a through-hole penetrating both substrates, and both substrates mutually send or receive an electric signal via the joint or the thorough-hole (see for instance, Japanese Unexamined Patent Application Publication No. 2017-117828). A usable example of the conductive material of the joint or a filler substance of the through-hole is copper.

As described in Japanese Patent No. 5773379 and Japanese Unexamined Patent Application Publication No. 2017-117828, a CMOS image sensor having a stack of a pixel substrate and logic substrate is structured such that the pixel substrate and the logic substrate are connected to each other in a region except for an electrode pad via only an output-signal wire extending from the pixel substrate, a pixel driving wire, power-source wires necessary for circuit operations of the respective substrates, and a ground wire. Wiring is completed within respective substrates in any of the circuits, in a portion except for the foregoing wires, which are essential for the connection between both substrates.

### SUMMARY

As seen in the foregoing known technique, a solid-state image pickup element having a structure where a pixel substrate and a logic substrate are stacked to be electrically connected together has been widely known. However, both substrates are connected together in a region except for the electrode pad region via minimal wires, such as the output-signal wire extending from the pixel, and each circuit block is completed within the corresponding substrate.

The pixel substrate and logic substrate that are to be stacked are produced through manufacturing processes different from each other, and hence, they have in some cases mutually different layout rules, including wire-to-wire spacing. At the beginning of design, one often decides the types of minimal wires that have to be connected between the pixel substrate and logic substrate, and the position of a joint where they are connected together, followed by proceeding to circuit layout individually for each of the substrates. It is hence difficult to form such an optimal layout not to eliminate wasted spaces in the entire stacked chip.

The chip size of semiconductor elements including solid-state image pickup elements directly leads to manufacturability and cost. A chip of smaller size is hence required, but circuit layout with limited metal wire layers and a narrow wiring spacing is more stringent. In a stacked chip, the pixel substrate and the logic substrate must have the same size, and hence, a size agreement with either of them having a larger size needs to be made. One of the substrates at this time has an empty space with no wires and no elements disposed therein, thus producing layout waste.

In a power-source wire or ground wire in a circuit with high power consumption, an excessively high wire resistance drops voltage instantly, possibly failing to perform a circuit operation as expected. These wires hence need to have sufficiently wide widths. Unfortunately, allocating a wiring space is more difficult along with decrease in chip size due to the foregoing trade-off relationship with chip size, thus making it difficult to lay out a wide power-source wire and a wide ground wire.

To achieve imaging at a high frame rate, a circuit operation that uses a higher-speed clock is required for solid-state image pickup elements. In a clock signal wire through which a high-speed clock signal passes, its waveform is particularly slows down easily under the influence of a wire resistance, and at a high wire resistance, the circuit operation sometimes cannot be done as expected. It is hence desired to provide such a layout that a wire for a high-speed clock signal has a small resistance as much as possible by, for instance, sufficiently widening the wire's width. Unfortunately, allocating a wiring space is more difficult along with decrease in chip size due to the foregoing trade-off relationship with chip size, thus making it difficult to lay out a wide clock signal wire.

One aspect of the disclosure has been made to solve the above problems. It is an object of the one aspect of the disclosure to offer a solid-state image pickup element that has a stack of a pixel substrate and logic substrate, and that can prevent a resistance that is exerted on wires while increasing wire flexibility to optimize a layout area, and to offer an electronic device that includes such a solid-state image pickup element.

To solve the above problems, a solid-state image pickup element according to one aspect of the disclosure includes the following: a pixel substrate having a pixel array where a unit pixel including a photoelectric-conversion element is disposed in rows and columns; a logic substrate having a logic circuit that relates to the pixel array, and stacked on the pixel substrate; and a joint portion joined in such a manner that uppermost-layer wires of the respective pixel substrate and logic substrate face each other, to electrically connect the pixel substrate and the logic substrate together, wherein the logic circuit has a first terminal and a second terminal that are nodes identical to each other, the node of the first terminal and the node of the second terminal are nodes that are used for a circuit operation on only the logic substrate, the joint portion includes a first wire connecting the first terminal to the pixel substrate, and a second wire connecting the second terminal to the pixel substrate, and the pixel substrate includes a first connection wire connecting the first wire and the second wire together.

To solve the above problems, a solid-state image pickup element according to another aspect of the disclosure includes the following: a pixel substrate having a pixel array where a unit pixel including a photoelectric-conversion element is disposed in rows and columns, and a pixel circuit that relates to the pixel array; a logic substrate having a logic circuit that relates to the pixel array, and stacked on the pixel substrate; and a joint portion joined in such a manner that uppermost-layer wires of the respective pixel substrate and logic substrate face each other, to electrically connect the pixel substrate and the logic substrate together, wherein the pixel circuit has a first terminal and a second terminal that are nodes identical to each other, the node of the first terminal and the node of the second terminal are nodes that are used for a circuit operation on only the pixel substrate, the joint portion includes a first wire connecting the first terminal to the logic substrate, and a second wire connecting the second terminal to the logic substrate, and the logic substrate includes a first connection wire connecting the first wire and the second wire together.

To solve the above problem, an electronic device according to one aspect of the disclosure includes the solid-state image pickup element according to one aspect of the disclosure.

These aspects of the disclosure can offer a solid-state image pickup element that can prevent a resistance that is exerted on wires while increasing wire flexibility to optimize a layout area, and the aspects can oiler an electronic device that includes such a solid-state image pickup element.

### BRIEF DESCRIPTION OF THE DRAWINGS

FIG. 1 is a sectional view of a solid-state image pickup element according to a first preferred embodiment;

FIG. 2 is a plan view of a pixel substrate provided in the solid-state image pickup element;

FIG. 3 is a plan view of a logic substrate provided in the solid-state image pickup element;

FIG. 4 is a circuit diagram of a unit pixel disposed on the pixel substrate;

FIG. 5 is a detailed sectional view of the solid-state image pickup element;

FIG. 6 schematically illustrates the relationship between the logic substrate and the pixel substrate;

FIG. 7 is a detailed sectional view of a modification of the solid-state image pickup element;

FIG. 8 is a detailed sectional view of another modification of the solid-state image pickup element;

FIG. 9 is a detailed sectional view of a solid-state image pickup element according to a second preferred embodiment;

FIG. 10 is a plan view of main components of a pixel substrate provided in a solid-state image pickup element according to a third preferred embodiment;

FIG. 11 is a detailed sectional view of a solid-state image pickup element according to a fourth preferred embodiment;

FIG. 12 is a detailed sectional view of a modification of the solid-state image pickup element according to the fourth preferred embodiment;

FIG. 13 is a detailed sectional view of another modification of the solid-state image pickup element according to the fourth preferred embodiment;

FIG. 14 is a detailed sectional view of another modification of the solid-state image pickup element according to the fourth preferred embodiment;

FIG. 15 is a schematic diagram of a camera according to a fifth preferred embodiment; and

FIG. 16 is a block diagram of the camera according to the fifth preferred embodiment.

### DESCRIPTION OF EMBODIMENTS

### First Preferred Embodiment

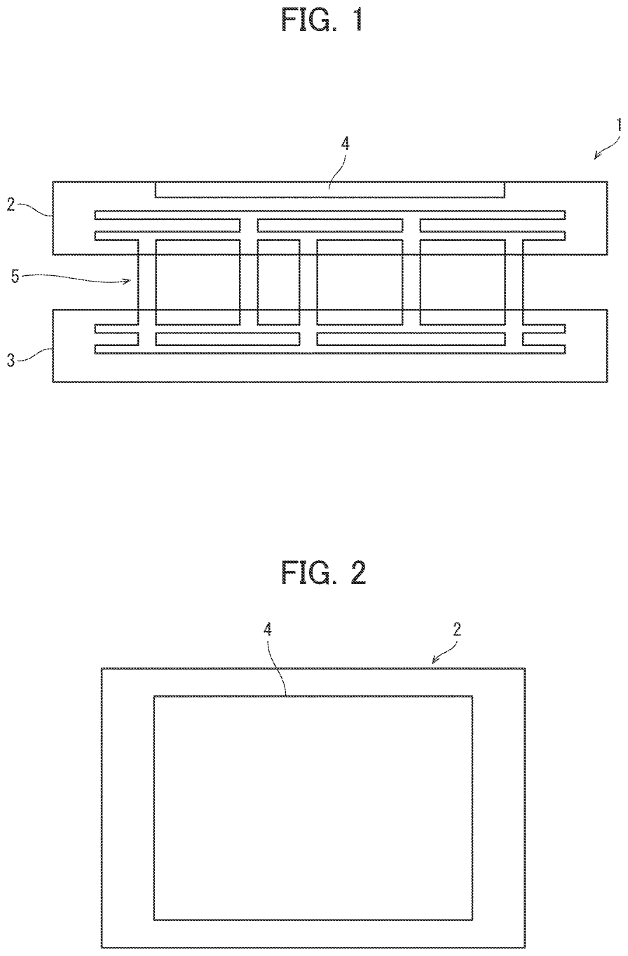

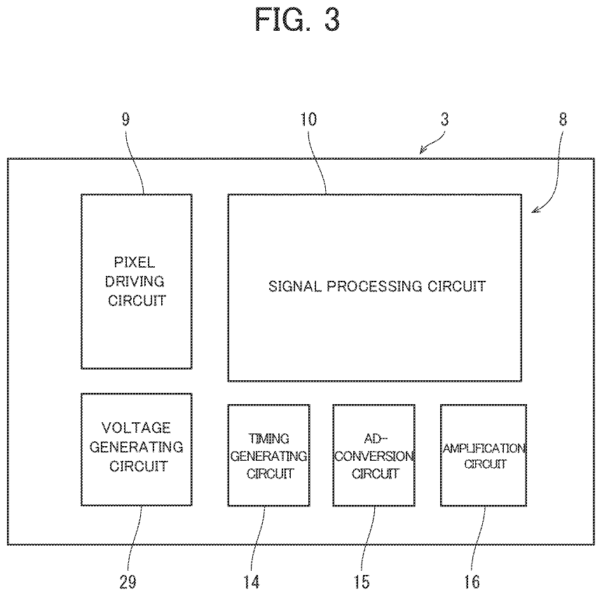

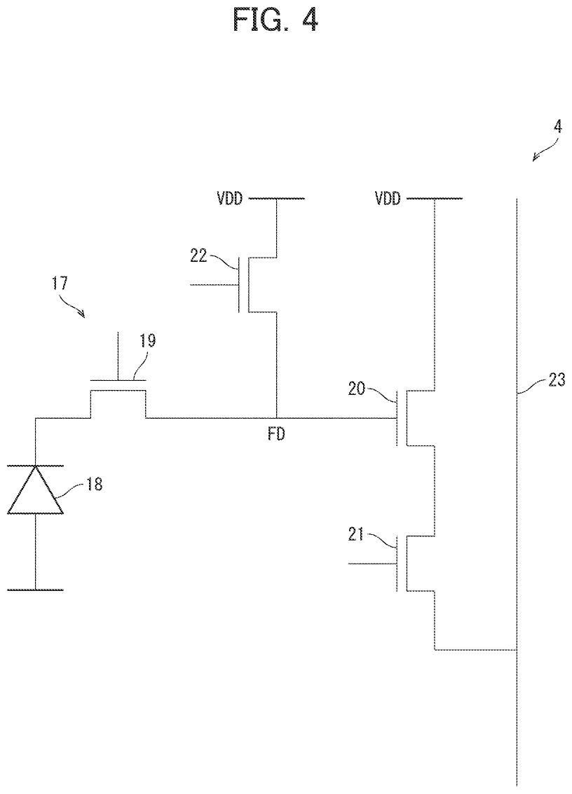

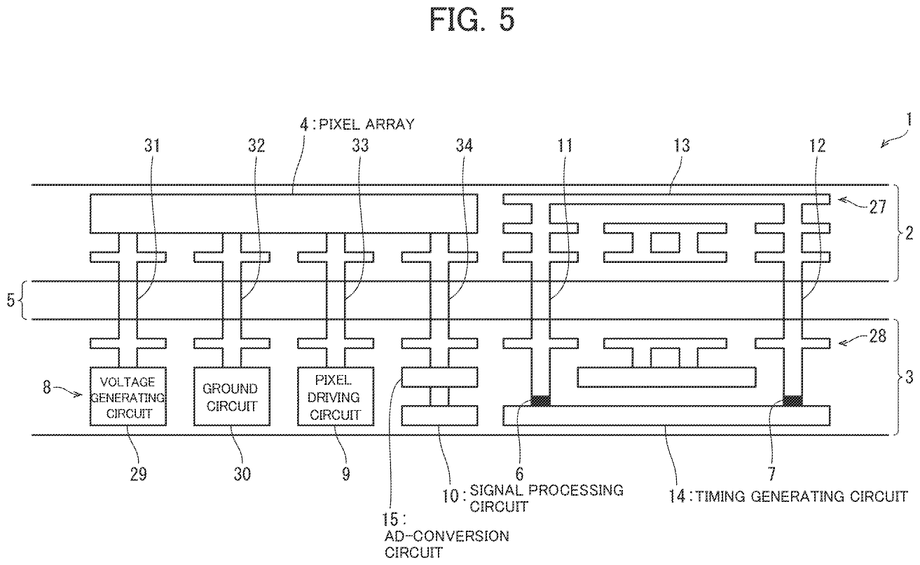

The following details one embodiment of the disclosure. FIG. 1 is a sectional view of a solid-state image pickup element 1 according to t first preferred embodiment. FIG. 2 is a plan view of a pixel substrate 2 provided in the solid-state image pickup element 1. FIG. 3 is a plan view of a logic substrate 3 provided in the solid-state image pickup element 1. FIG. 4 is a circuit diagram of a unit pixel 17 disposed in a pixel array 4 of the pixel substrate 2. FIG. 5 is a detailed sectional view of the solid-state image pickup element 1.

The solid-state image pickup element 1 includes the following: the pixel substrate 2 having the pixel array 4 where a unit pixel 17 including a photo diode 18 (photoelectric-conversion element) disposed in rows and columns; the logic substrate 3 having a logic circuit 8 that relates to the pixel array 4, and stacked on the pixel substrate 2; and a joint portion 5 joined in such a manner that uppermost-layer wires of the respective pixel substrate 2 and logic substrate 3 face each other, to electrically connect the pixel substrate 2 and the logic substrate 3 together.

The logic circuit 8 includes the following: a pixel driving circuit 9 for driving the unit pixel 17 of the pixel array 4; a signal processing circuit 10 for processing a signal output from the pixel array 4; a voltage generating circuit 29 that generates a voltage level that is different from a voltage input from outside via a chip electrode pad; a timing generating circuit 14 that generates a clock signal that constitutes a basis for each circuit operation; an AID-conversion circuit 15 that AD-converts a signal output from the pixel array 4; and an amplification circuit 16 that subjects image data that is output to the chip outside to an analog gain or a digital gain to amplify the image data.

The timing generating circuit 14 has a first terminal 6 and a second terminal 7 that are nodes identical to each other. The nodes of the first terminal 6 and second terminal 7 are nodes that are used for a circuit operation in only the logic substrate 3.

It is noted that although the following describes an instance where the first terminal 6 and the second terminal 7 are provided in the timing generating circuit 14, one aspect of the disclosure is not limited to this instance. The first terminal 6 and the second terminal 7 need to be provided in the logic circuit 8. For instance, the first terminal 6 and the second terminal 7 may be provided in at least one of the pixel driving circuit 9, signal processing circuit 10, voltage generating circuit 29, AD-conversion circuit 15 and amplification 16.

The joint portion 5 includes a first wire 11 connecting the first terminal 6 to the pixel substrate 2, and a second wire 12 connecting the second terminal 7 to the pixel substrate 2. The pixel substrate 2 includes a first connection wire 13 connecting the first wire 11 and the second wire 12 together.

The pixel substrate 2 includes a first wire layer 27. The logic substrate 3 includes a second wire layer 28. The first connection wire 13 is formed in the first wire layer 27. The first terminal 6 and the second terminal 7 are not electrically connected together in the second wire layer 28. The first terminal 6 and the second terminal 7 are electrically connected together in only the first wire layer 27.

The first terminal 6 is preferably one of a power source terminal and a ground terminal, and the second terminal 7 is preferably the other one of the power source terminal and the ground terminal.

The first wire layer 27 is preferably a multi-layer wire layer. The first connection wire 13 is preferably formed in one or more lavers of the multi-layer wire layer.

The pixel substrate 2 and the logic substrate 3 have their shapes identical to each other, and their areas identical to each other, and the solid-state image pickup element 1 is formed in a chip form.

The pixel substrate 2 has the pixel array 4 with the unit pixel 17 shown in FIG. 4 disposed in rows and columns two-dimensionally. A pixel output signal read from the pixel array 4 is supplied to the logic substrate 3, undergoes various kinds of signal processing in the logic substrate 3 and is then output to the chip outside.

Light entered the unit pixels 17 undergoes photoelectric conversion by the photo diode 18, formed on the pixel substrate 2 (e.g., a silicon substrate), and accumulates as a signal charge, as illustrated in FIG. 4. The pixel transistors include four transistors: a transfer transistor 19, a reset transistor 22, an amplification transistor 20, and a selection transistor 21.

Then, the signal charges accumulated in the photo diode 18 are transferred to a floating diffusion FD by turning on the transfer transistor 19. Next, the signal charges transferred to the floating diffusion FD are amplified by turning on the amplification transistor 20. After that, the amplified signal charges are read to the outside of the pixel array 4 through a vertical signal line 23 by turning on the selection transistor 21 corresponding to a pixel address that is to be read. Then, turning on the reset transistor 22 discards the signal charges transferred to the floating diffusion FD to initialize the potential of the floating diffusion FD.

The logic circuit 8 includes various logic circuits, including the voltage generating circuit 29, the pixel driving circuit 9, the AD-conversion circuit 15, the signal processing circuit 10, the timing generating circuit 14 and the amplification circuit 16. The pixel driving circuit 9 supplies a pixel drive signal to the foregoing pixel transistors within the pixel array 4 for accumulation, transfer, amplification and read of the signal charges to thus drive the pixel. The AD-conversion circuit 15 receives the pixel output signal read from the pixel array 4 to subject the pixel output signal to analog-to-digital conversion. The AD-converted pixel output signal undergoes some kinds of processing in the signal processing circuit 10, such as subtraction of zero level from its signal level to remove fixed-patter variations for each pixel, and is then output to the chip outside as image data. The voltage generating circuit 29 generates a voltage level that is different from a voltage input from the outside via the chip electrode pad. This voltage is used as, for instance, power-source voltage. The timing generating circuit 14 generates a clock signal that constitutes a basis for each circuit operation. A higher-speed clock signal, i.e., a larger-frequency clock signal, enables a higher-speed circuit operation. The amplification circuit 16 subjects the image data that is output to the chip outside to an analog gain or a digital gain to amplify the image data.

The joint portion 5, which electrically connects the pixel substrate 2 and the logic substrate 3 together when both substrates are stacked, is an aggregation of joints of conductive material that couples the uppermost-layer metals of both substrates together, A usable example of the conductive material of the joints is copper.

As clearly seen from FIG. 5, the solid-state image pickup element 1 in the first preferred embodiment is configured such that the joint portion 5 electrically connects together the uppermost-layer metals of the respective wire layers of the pixel substrate 2, having the pixel array 4, and the logic substrate 3, having the signal processing circuit 10, and such that both substrates send or receive electric signals, including a pixel output signal. A wire 31 is a power-source wire and supplies a pixel power source generated in the voltage generating circuit 29 of the logic substrate 3 to the pixel substrate 2. A wire 32 is a ground wire and supplies, similarly to the power-source wire, a ground potential from a ground circuit 30 of the logic substrate 3 to the pixel substrate 2. A wire 33 is a pixel-drive signal wire, connects together the pixel driving circuit 9 of the logic substrate 3 and the gates of the pixel transistors included in the pixel array 4 of the pixel substrate 2 and drives the pixel through accumulation, transfer, amplification and read of signal charges. A wire 34 is a pixel-output signal wire and connects a pixel signal output from the pixel array 4 of the pixel substrate 2 to the AD-conversion circuit 15 of the logic substrate 3. The pixel signal is sent to the AD-conversion circuit 15 and then to the signal processing circuit 10, undergoes various kinds of signal processing and is then output to the chip outside as image data.

In the stacked substrates of a known solid-state image pickup element, only the foregoing power-source wire, ground wire, pixel-drive signal wire and pixel-output signal wire are connected between the pixel substrate 2 and the logic substrate 3 via the joint portion 5. As described above, only the identical nodes provided in the circuits on both of the pixel substrate 2 and logic substrate 3 are wired between both substrates via the joint portion 5.

The following describes the structure of a characteristic part of the solid-state image pickup element 1 according to the first preferred embodiment shown in FIG. 5 in comparison to the foregoing. The first terminal 6 and the second terminal 7 of the same node, provided in the timing generating circuit 14 of the logic substrate 3, are not connected together directly by using the second wire layer 28 of the logic substrate 3, but are connected together through the first connection wire 13 by using an empty space in the first wire layer 27 of the pixel substrate 2, coupled via the first wire 11 and the second wire 12. The nodes of the first terminal 6 and second terminal 7 are used in only the timing generating circuit 14 of the logic substrate 3 and are not used in the pixel substrate 2; hence, wiring can be completed originally within only the logic substrate 3. However, to connect he first terminal 6 and the second terminal 7 together easily, the solid-state image pickup element 1 according to the first preferred embodiment is structured such that a wire is routed via the first wire layer 27 of the pixel substrate 2, on which the nodes of the first terminal 6 and second terminal 7 are not used.

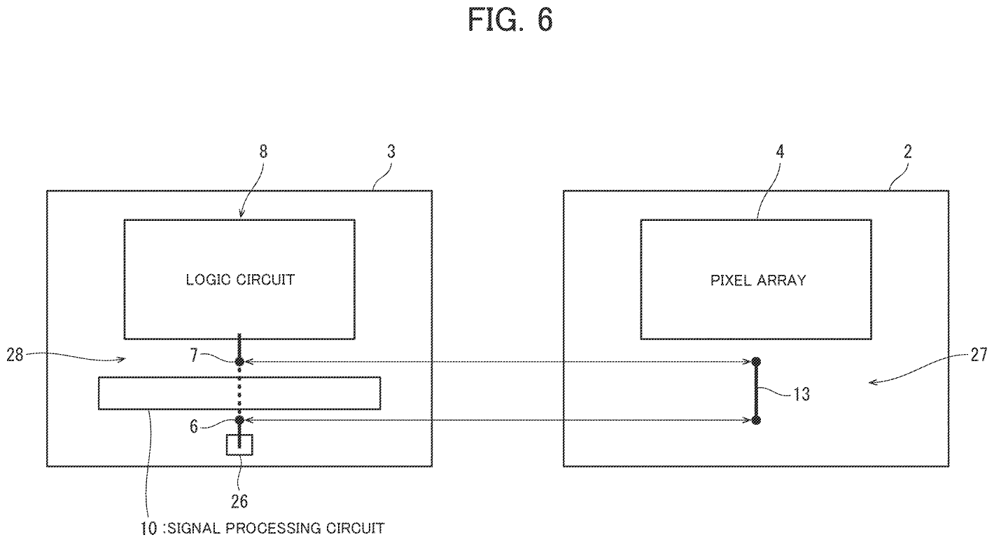

FIG. 6 schematically illustrates the relationship between the logic substrate 3 and the pixel substrate 2.

In an attempt to connect the first terminal 6 and the second terminal 7 together via a wire, connection in the logic substrate 3 is difficult in some cases in view of layout. An example of such difficult cases is one illustrated in FIG. 6, where the signal processing circuit 10 is disposed between the first terminal 6 provided on the electrode pad 26 of the power source for driving the logic circuit 8 and the second terminal 7 provided on the logic circuit 8. In this case, to connect the first terminal 6 and the second terminal together on the logic substrate 3, the signal processing circuit 10 needs to be separated into two blocks, and a wire needs to be routed between the two block to connect the first terminal 6 and the second terminal 7 together. This unfortunately increases a layout area and breaks the arrangement periodicity of the signal processing circuit 10, thus producing a large layout impact.

At this time, connecting the first terminal 6 and the second terminal 7 together in an empty space by using only the first wire layer 27 of the pixel substrate 2, rather than forcibly connecting the first terminal 6 and the second terminal 7 together in the second wire layer 28 of the logic substrate 3 can minimize the layout area.

The following are determined at the start of design in the first preferred embodiment: what kind of wires are to be used for connection between the pixel substrate 2 and the logic substrate 3; and where joints at which these wires are connected are to be positioned. Here, in a known solid-state image pickup element, one determines connecting only wires, such as a pixel-output signal wire, that are essential for the structure of a stacked chip and does not basically increase the kind of wires for connection at the subsequent design stage. In the solid-state image pickup element 1 according to the first preferred embodiment by contrast, one adds joints and wires for connection between both substrates in some cases, depending on the conditions of a circuit layout at the subsequent design stage.

Next, the arrangement of circuit blocks is determined for each of the pixel substrate 2 and logic substrate 3, and the layout of each circuit block proceeds. At this time, a chip-size agreement with either of the substrates that are to be stacked, having a larger size is made. The pixel substrate 2 and logic substrate 3 that are to be stacked are produced through manufacturing processes different from each other, and hence, they have in some cases mutually different layout rules, including wire-to-wire spacing.

In a known solid-state image pickup element, one often performs circuit layout individually for each of the pixel substrate 2 and logic substrate 3. In the solid-state image pickup element 1 according to the first preferred embodiment by contrast, one performs layout simultaneously so as to be able to effectively use spaces in both substrates while keeping such different layout rules about both substrates in mind. There is an empty space remaining in at least one of the substrates, because a chip-size agreement with either of the substrates having a larger size is made. As illustrated in FIG. 5, for connection between the first terminal 6 and second terminal 7, provided in the timing generating circuit 14 of the logic substrate 3, when the second wire layer 28 of the logic substrate 3 is tight on layout space, whereas the first wire layer 27 of the pixel substrate 2 has an empty space, a wiring structure can be established where the first wire 11 and the second wire 12 are used to connect the terminals via the first wire layer 27 of the pixel substrate 2.

The solid-state image pickup element I according to the first preferred embodiment enables such a flexible layout that the first terminal 6 and the second terminal 7 can be connected together by effectively using the empty space in the first wire layer 27 of the pixel substrate 2, even when their connection is difficult in the second wire layer 28 of the logic substrate 3 due to spacing. As described above, optimizing the layout area of each circuit block in units of multiple staked substrates can reduce the total number of wire lavers and can reduce the size of an entire chip. Reducing the number of wire layers can reduce masks for production, thereby reducing costs. Reducing the chip size increases the number of chips that are to be mounted on a semiconductor wafer, thus reducing costs for manufacture.

As described above, in the solid-state image pickup element 1, which has a stack of the pixel substrate 2 and logic substrate 3, establishing such a structure as to connect a wire used for a circuit operation on only one of the substrates to the other substrate where the wire is not used for the circuit operation, and to pass the wire through the wire layer of the other substrate to connect the wire again to the one substrate can offer a solid-state image pickup element that can reduce a resistance that is exerted on the wire while increasing the flexibility of the wire to optimize a layout area.

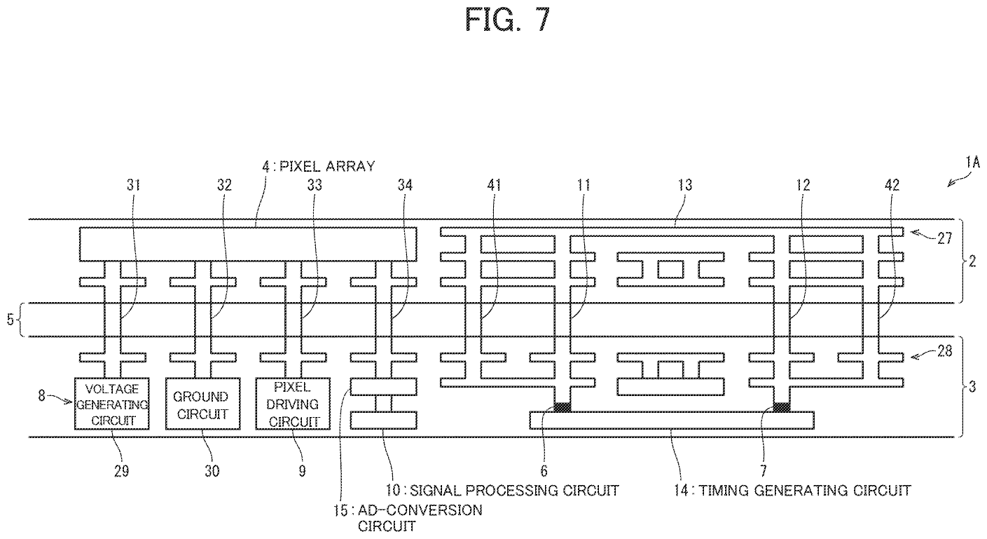

FIG. 7 is a detailed sectional view of a solid-state image pickup element 1A according to a modification. Components similar to those previously described will be denoted by the same reference signs, and their detailed description will not be repeated.

The first terminal 6 and the second terminal 7 may be connected to the pixel substrate 2 via a plurality of joints. As illustrated in NG. 7 for instance, the joint portion 5 includes, in addition to the first wire 11 and the second wire 12, a third wire 41 connecting the first terminal 6 to the pixel substrate 2, and a fourth wire 42 connecting the second terminal 7 to the pixel substrate 2. The third wire 41 is connected to the first wire 11 electrically in parallel. The fourth wire 42 is connected to the second wire 12 electrically in parallel. It is noted that the first wire 11 and the third wire 41 need to be connected electrically in parallel and need not to be arranged physically side-by-side; they may be physically spaced from each other. Likewise, the second wire 12 and the fourth wire 42 need not to be arranged physically side-by-side; they may be physically spaced from each other.

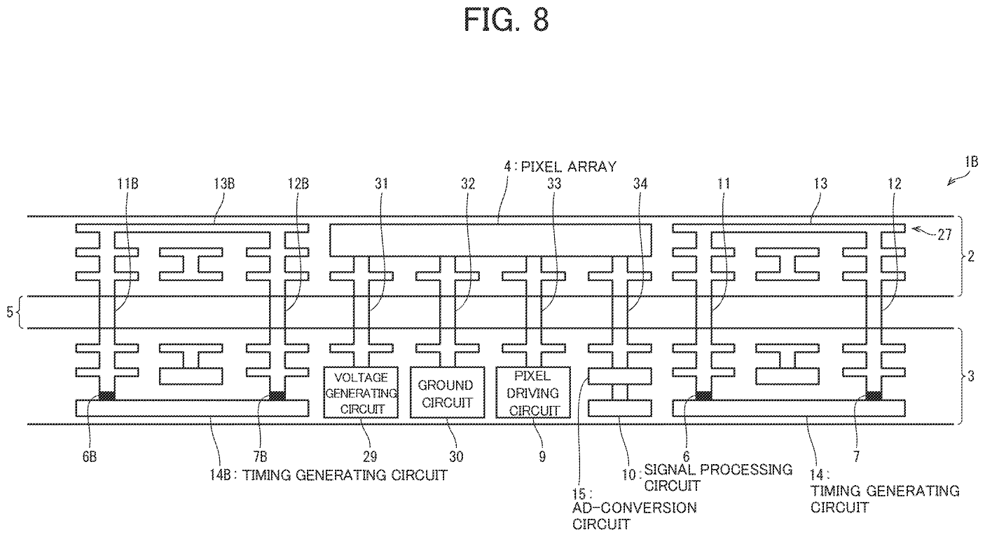

FIG. 8 is a detailed sectional view of a solid-state image pickup element 1B according to another modification. Components similar to those previously described will be denoted by the same reference signs, and their detailed description will not be repeated.

Two or more pairs of terminals having their respective nodes different from each other may be provided. As illustrated in FIG. 8 for instance, the solid-state image pickup element 1B further includes a timing generating circuit 14B.

The timing generating circuit 14B further has a third terminal 6B and a fourth terminal 7B that are other nodes identical to each other. As described above, two pairs are provided: one is a pair of the first terminal 6 and second terminal 7, and the other is a pair of the third terminal 6B and fourth terminal 7B. The joint portion 5 further includes a fifth wire 11B connecting the third terminal 6B to the pixel substrate 2, and a sixth wire 12B connecting the fourth terminal 7B to the pixel substrate 2. The pixel substrate 2 further includes a third connection wire 13B connecting the fifth wire 11B and the sixth wire 12B together.

In some cases, a semiconductor element like one according to this preferred embodiment uses a plurality of kinds of power sources having different voltages within the chip. Examples of such power sources include a power source for pixel drive, and a power source for logic-circuit drive. Further, other than power sources and a ground terminal, there are some nodes where the resistance of a wire, such as a high-speed clock signal line, tends to have a serious effect. Applying the structure proposed in this preferred embodiment (i.e., a structure where a wire passes through the other one of the substrates) to not only one of these nodes, but also some of these nodes can handle the wire resistance between terminals having different nodes.

### Second Preferred Embodiment

The following describes another preferred embodiment of the disclosure. It is noted that for convenience in description, components having the same functions as components described in the foregoing preferred embodiment will be denoted by the same signs, and their description will not be repeated.

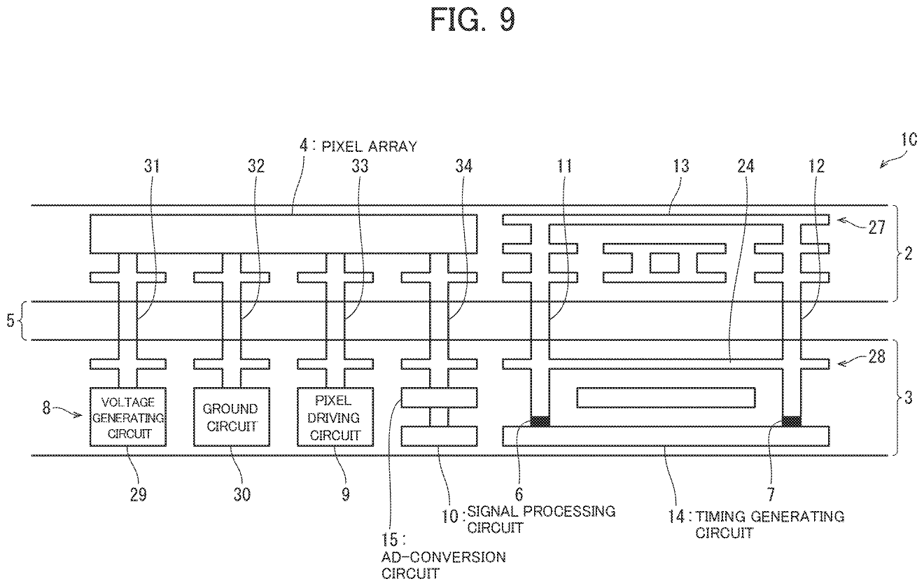

FIG. 9 is a detailed sectional view of a solid-state image pickup element 1C according to the second preferred embodiment.

As clearly seen from FIG. 9, the solid-state image pickup element 1C in the second preferred embodiment is configured, like that in the first preferred embodiment, such that the uppermost-layer metals in the respective wire layers of the pixel substrate 2, having the pixel array 4, and of the logic substrate 3, having the signal processing circuit 10, are electrically connected together by the joint portion 5. Both substrates are connected together by wires, including a power-source wire, a ground wire, a pixel-drive signal wire, and a pixel-output signal wire.

The following describes the structure of a characteristic part of the solid-state image pickup element 1C according to the second preferred embodiment shown in FIG. 9. The first terminal 6 and the second terminal 7 of the same node, provided in the timing generating circuit 14 of the logic substrate 3, are connected together directly by using the second connection wire 24 in the second wire layer 28 of the logic substrate 3 and are also connected together through the first connection wire 13 by also using an empty space in the first wire layer 27 of the pixel substrate 2, coupled via the first wire 11 and the second wire 12. The nodes of the first terminal 6 and second terminal 7 are used in only the timing generating circuit 14 of the logic substrate 3 and are not used in the pixel substrate 2; hence, wiring can be completed originally within only the logic substrate 3. However, to reduce a resistance that is exerted on the wires, the solid-state image pickup element 1C according to the second preferred embodiment includes a characteristic wiring structure where the first connection wire 13 in the first wire layer 27 of the pixel substrate 2, in which the nodes of the first terminal 6 and second terminal 7 are not used, is used for backing.

The procedure of designing the wiring structure in the second preferred embodiment, which is similar to the procedure of designing the foregoing wiring structure in the first preferred embodiment, will not be described repeatedly.

The solid-state image pickup element 1C according to the second preferred embodiment enables such a layout as to connect, without difficulty, a wide wire in the first wire layer 27 of the pixel substrate 2 by using the foregoing wiring structure, even when two or more terminals cannot be connected together in the second wire layer 28 of the logic substrate 3 via a sufficiently wide wire. Accordingly, the wire is backed in the first wire layer 27 of the stacked pixel substrate 2, and the resistance exerted on the wire between the first terminal 6 and second terminal 7 that is located on the logic substrate 3 can be reduced, thereby preventing a voltage drop. Establishing this backed-wire structure in the power-source wire and ground wire can strengthen the power source and ground of the circuit. Further, a high-speed clock signal line and other lines need to have a wide width; accordingly, applying this structure to them can prevent clock waveform rounding, The solid-state image pickup element 1C, when can implement a higher-speed clock signal, can read image data more rapidly, thus achieving the solid-state image pickup element IC of high frame rate.

### Third Preferred Embodiment

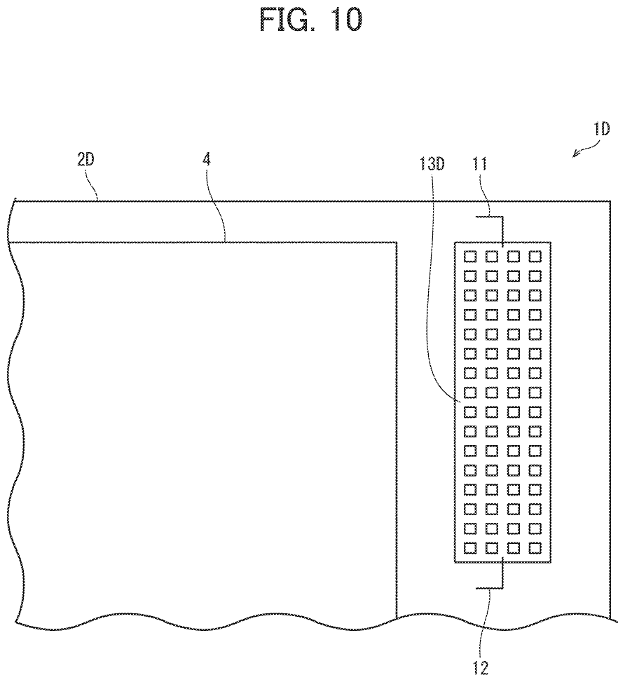

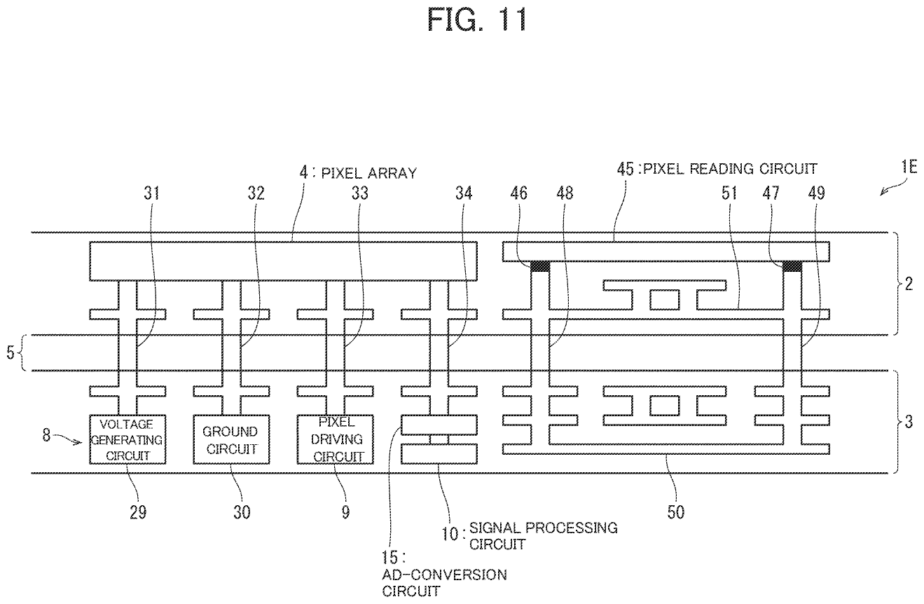

FIG. 10 is a plan view of main components of a pixel substrate 2D provided in a solid-state image pickup element 1D according to the third preferred embodiment. Components similar to components previously described will be denoted by the same reference signs, and their detailed description will not be repeated.

The solid-state image pickup element 1D in the third preferred embodiment includes a grid wire structure where wires crisscross in such a lattice manner as illustrated in FIG. 10, instead of the foregoing wire in the first and second preferred embodiments, which is connected via an empty space in the first wire layer 27 of the pixel substrate 2. The first wire 11 and the second wire 12 are connected together through a first connection wire 13D formed in a grid manner. Using a wide wire having a predetermined or larger width is commonly prohibited in a layout rule, but routing wires each having a narrow width in a grid manner, like the first connection wire 13D, can achieve a layout that reduces a wire resistance as much as possible while obeying the layout rule.

Consequently, the resistance of the first connection wire 13D connecting in the first wire layer 27 of the pixel substrate 2D can be reduced, thereby preventing a voltage drop and clock-signal waveform rounding more strongly.

### Fourth Preferred Embodiment

A solid-state image pickup element according to the fourth preferred embodiment includes a wiring structure in which the first terminal 6 and second terminal 7 of the same node located in a circuit of the pixel substrate 2 are connected together via an empty space in the second wire layer 28 of the logic substrate 3. The logic substrate 3 has taken the place of the pixel substrates 2 of the solid-state Image pickup elements 1, 1A, 1B and 1C according to the first to third preferred embodiments. Further, the procedure and effect of the structure according to the fourth preferred embodiment are similar to those according to the first to third preferred embodiments.

FIG. 11 is a detailed sectional view of a solid-state image pickup element 1E according to the fourth preferred embodiment. Components similar to those previously described will be denoted by the same reference signs, and their detailed description will not be repeated.

The solid-state image pickup element 1E includes the following: the pixel substrate 2 having the pixel array 4, and a pixel reading circuit 45 (pixel circuit) that relates to the pixel array 4; the logic substrate 3 having the logic circuit 8 that relates to the pixel array 4, and stacked on the pixel substrate 2; and the joint portion 5 joined in such a manner that uppermost-layer wires of the respective pixel substrate 2 and logic substrate 3 face each other, to electrically connect the pixel substrate 2 and the logic substrate 3 together.

The pixel reading circuit 45 has a first terminal 46 and a second terminal 47 that are nodes identical to each other. The nodes of the first terminal 46 and second terminal 47 are nodes that are used for a circuit operation on only the pixel substrate 2.

The joint portion 5 includes a first wire 48 connecting the first terminal 46 to the logic substrate 3, and a second wire 49 connecting the second terminal 47 to the logic substrate 3. The logic substrate 3 includes a first connection wire 50 connecting the first wire 48 and the second wire 49 together.

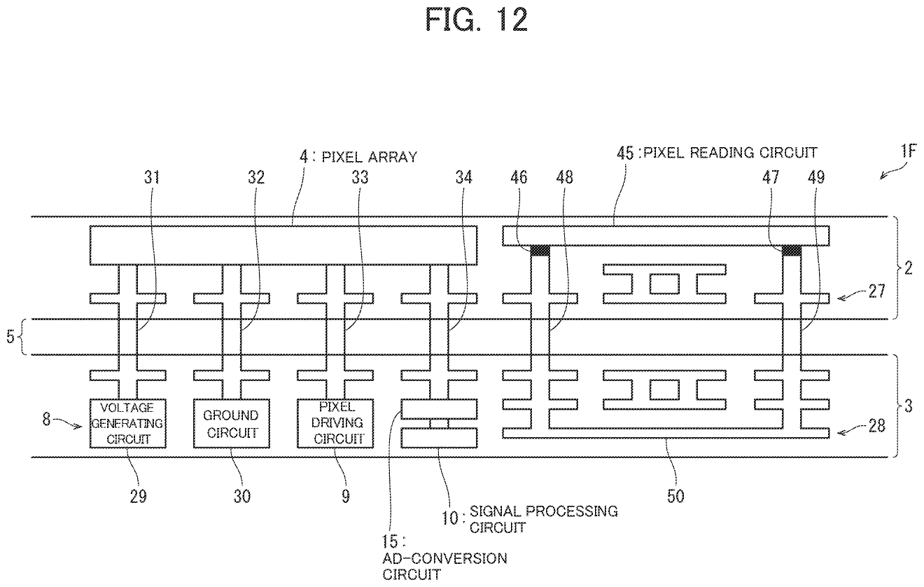

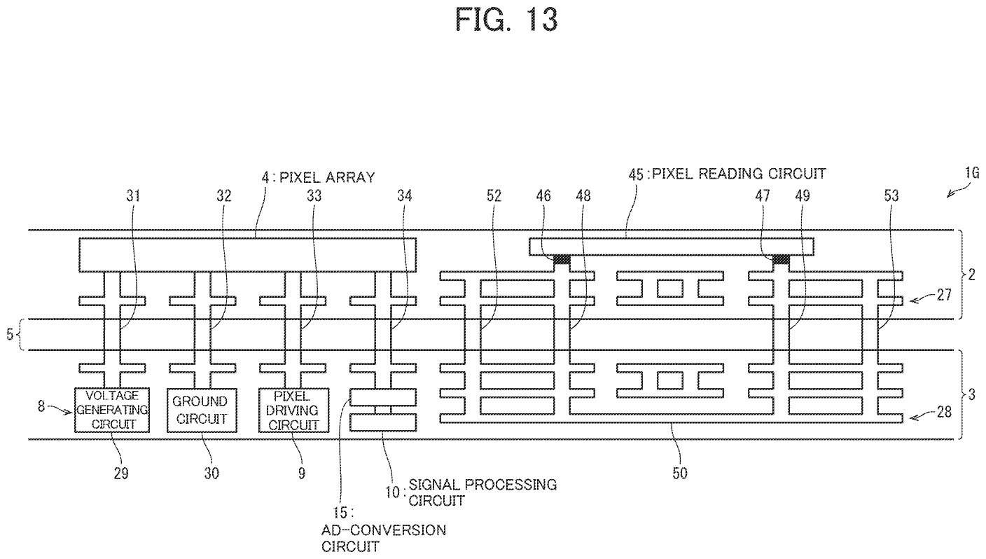

FIG. 12 is a detailed sectional view of a solid-state image pickup element 1F according to the fourth preferred embodiment. Components similar to those previously described will be denoted by the same reference signs, and their detailed description will not be repeated.

The pixel substrate 2 includes the first wire layer 27. The logic substrate 3 includes the second wire layer 28. The first terminal 46 and the second terminal 47 are not electrically connected together in the first wire layer 27. The first terminal 46 and the second terminal 47 are electrically connected together in only the second wire layer 28.

FIG. 13 is a detailed sectional view of a solid-state image pickup element 1G according to the fourth preferred embodiment. Components similar to those previously described will be denoted by the same reference signs, and their detailed description will not be repeated.

The joint portion 5 further includes a third wire 52 connecting the first terminal 46 to the logic substrate 3, and a fourth wire 53 connecting the second terminal 47 to the logic substrate 3.

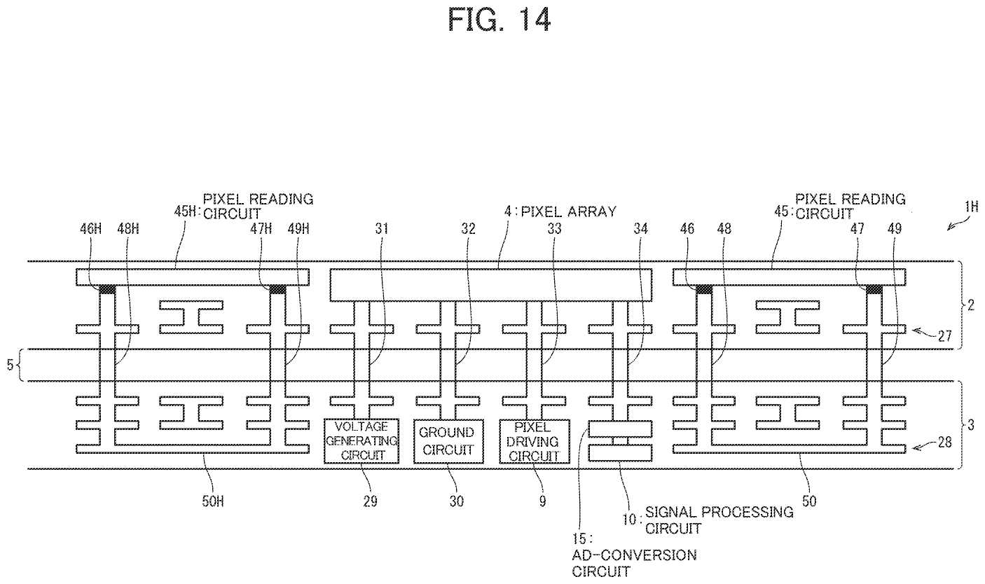

FIG. 14 is a detailed sectional view of a solid-state image pickup element 1H according to the fourth preferred embodiment. Components similar to those previously described will be denoted by the same reference signs, and their detailed description will not he repeated.

The solid-state image pickup element 1H includes a pixel reading circuit 45H. The pixel reading circuit 45H has a third terminal 46H and a fourth terminal 47H that are other nodes identical to each other.

The joint portion 5 includes a fifth wire 48H connecting the third terminal 46H to the logic substrate 3, and a sixth wire 49H connecting the fourth terminal 47H to the logic substrate 3. The logic substrate 3 includes a third connection wire 50H connecting the fifth wire 48H and the sixth wire 49H together.

### Modification

The solid-state image pickup elements according to the first to fourth preferred embodiments can be combined freely.

### Fifth Preferred Embodiment

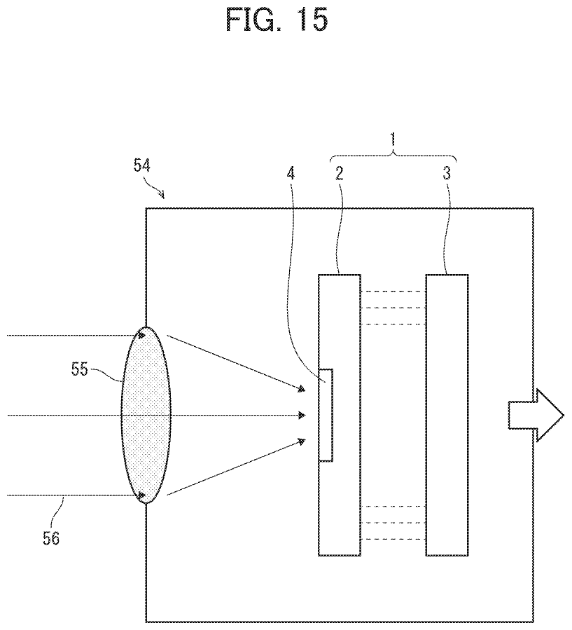

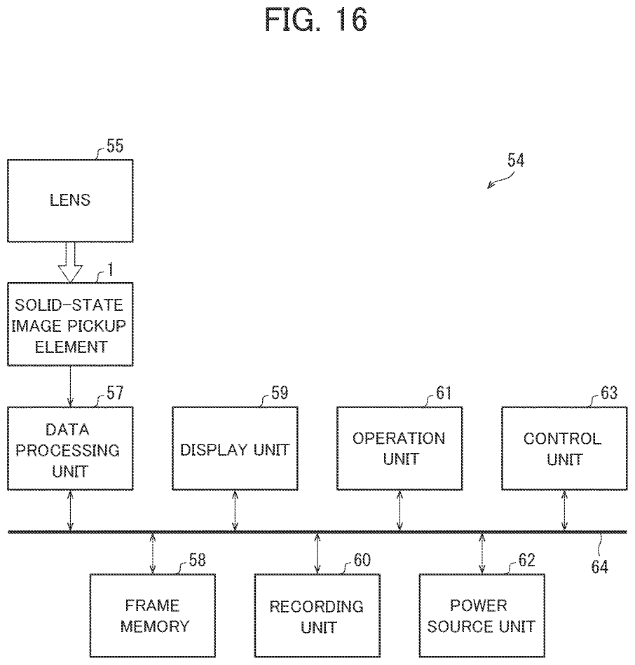

FIG. 15 is a schematic diagram of a camera 54 (electronic device) according to a fifth preferred embodiment. Components similar to those previously described will be denoted by the same reference signs, and their detailed description will not be repeated.

The camera 54 includes the solid-state image pickup element 1, and a lens 55 that concentrates, as incident light, light 56 emitted from a subject onto the pixel array 4 provided on the pixel substrate 2 of the solid-state image pickup element 1.

FIG. 16 is a block diagram of the camera 54. Components similar to those previously described will be denoted by the same reference signs, and their detailed description will not be repeated.

The camera 54 according to the fifth preferred embodiment includes the following: the lens 55; the solid-state image pickup element 1; a data processing unit 57 composed of, but not limited to, a digital signal processor (DSP) that subjects data generated by the solid-state image pickup element 1 to various kinds of processing (e.g., demosaicing) to generate image data; a frame memory 58 that stores data when the data processing unit 57 performs data processing; a display unit 59 that displays the image data generated by the data processing unit 57, an image for operation, and other data; a recoding unit 60 that records, as necessary, the image data generated by the data processing unit 57; an operation unit 61 composed of, but not limited to, a button or touch panel for receiving user operations; a power source unit 62 that supplies power for the camera 54 to operate; a control unit 63 that controls the operation of the camera 54; and a bus 64 connecting the foregoing individual units. It is noted that the camera 54 may be configured in such a manner that part of the data processing unit 57 is provided on the logic substrate 3 of the solid-state image pickup element 1.

Firstly, light entered from where a subject is located is concentrated on the lens 55 and forms an image on the solid-state image pickup element 1. Then, a signal undergone photoelectric conversion in the solid-state image pickup element 1 passes through a signal processing circuit including the data processing unit 57 and is then output to a display or other units.

### SUMMARY

A solid-state image pickup element 1, 1A to 1D according to a first aspect of the disclosure includes the following: a pixel substrate 2 having a pixel array 4 where a unit pixel 17 including a photoelectric-conversion element (photo diode 18) is disposed in rows and columns; a logic substrate 3 having a logic circuit 8 that relates to the pixel array 4, and stacked on the pixel substrate 2; and a joint portion 5 joined in such a manner that uppermost-layer wires of the respective pixel substrate 2 and logic substrate 3 face each other, to electrically connect the pixel substrate 2 and the logic substrate 3 together, wherein the logic circuit 8 (timing generating circuit 14) has a first terminal 6 and a second terminal 7 that are nodes identical to each other, the node of the first terminal 6 and the node of the second terminal 7 are nodes that are used for a circuit operation on only the logic substrate 3, the joint portion 5 includes a first wire 11 connecting the first terminal 6 to the pixel substrate 2, and a second wire 12 connecting the second terminal 7 to the pixel substrate 2, and the pixel substrate 2 includes a first connection wire 13, 13B connecting the first wire 11 and the second wire 12 together.

In the foregoing configuration, the first terminal and the second terminal, which are identical nodes of the logic circuit provided on the logic substrate, are connected together via the first connection wire, provided on the pixel substrate. Accordingly, an empty space, when produced in the pixel circuit stacked on the logic circuit, can be effectively used for connection between the first terminal and second terminal of the logic circuit. This can prevent a resistance that is exerted on the wires while increasing wire flexibility to optimize a layout area.

The solid-state image pickup element 1, 1A, 1B according to a second aspect of the disclosure is preferably configured, in the first aspect, such that the pixel substrate 2 includes a first wire layer 27, such that the logic substrate 3 includes a second wire layer 28, such that the first terminal 6 and the second terminal 7 are not electrically connected together in the second wire layer 28, and such that the first terminal 6 and the second terminal 7 are electrically connected together in only the first wire layer 27.

In the foregoing configuration, connecting the first terminal and second terminal of the logic circuit together in an empty space by using only the first wire layer on the pixel substrate when it is difficult for the logic substrate in layout to have a space for wire connection between them, can minimize the layout area.

The solid-state image pickup element 1A according to a third aspect of the disclosure is preferably configured, in the first or second aspect, such that the logic circuit 8 includes a pixel driving circuit 9 for driving the unit pixel 17, and a signal processing circuit 10 for processing a signal output from the pixel array 4, and such that the joint portion 5 further includes a third wire 41 connecting the first terminal 6 to the pixel substrate 2, and a fourth wire 42 connecting the second terminal 7 to the pixel substrate 2.

The foregoing configuration enables the first terminal of the logic circuit to be connected to the pixel substrate via a plurality of joints and enables the second terminal of the logic circuit to be connected to the pixel substrate via a plurality of joints.

The solid-state image pickup element 1, 1A to 1D according to a fourth aspect of the disclosure is preferably configured, in any one of the first to third aspects, such that the first terminal 6 is one of a power source terminal and a ground terminal, and such that the second terminal 7 is another one of the power source terminal and the ground terminal.

The foregoing configuration can sufficiently widen the widths of a power-source wire and ground wire on a circuit that consumes large power.

The solid-state image pickup element 1B according to a fifth aspect of the disclosure is preferably configured, in any one of the first to fourth aspects, such that the logic circuit 8 further has a third terminal 6B and a fourth terminal 7B that are other nodes identical to each other, such that the joint portion 5 further includes a fifth wire 11B connecting the third terminal 6B to the pixel substrate 2, and a sixth wire 12B connecting the fourth terminal 7B to the pixel substrate 2, and such that the pixel substrate 2 further includes a third connection wire 13B connecting the fifth wire 11B and the sixth wire 12B together.

The foregoing configuration can prevent a resistance that is exerted on the wires while increasing the flexibility of the wire connecting the first terminal and second terminal, in two or more pairs, having mutually different nodes, to optimize the layout area.

The solid-state image pickup element ID according to a sixth aspect of the disclosure is preferably configured, in the second aspect, such that the first wire layer 27 is a multi-layer wire layer, such that the first connection wire 13D is formed in one or more layers of the multi-layer wire layer, and such that the first connection wire 13D has a structure including a plurality of the first connection wires 13D connected together while crisscrossing in a lattice manner.

In the foregoing configuration, routing wires each having a narrow width in a grid manner can achieve a layout that reduces a wire resistance as much as possible while obeying a layout rule.

A solid-state image pickup element 1E to 1H according to a seventh aspect of the disclosure includes the following: a pixel substrate 2 having a pixel array 4 where a unit pixel 17 including a photoelectric-conversion element (photo diode is disposed in rows and columns, and a pixel circuit (pixel reading circuit 45) that relates to the pixel array 4; a logic substrate 3 having a logic circuit 8 that relates to the pixel array 4, and stacked on the pixel substrate 2; and a joint portion 5 joined in such a manner that uppermost-layer wires of the respective pixel substrate 2 and logic substrate 3 face each other, to electrically connect the pixel substrate 2 and the logic substrate 3 together, wherein the pixel circuit (pixel reading circuit 45) has a first terminal 46 and a second terminal 47 that are nodes identical to each other, the node of the first terminal 46 and the node of the second terminal 47 are nodes that are used for a circuit operation on only the pixel substrate 2, the joint portion 5 includes a first wire 48 connecting the first terminal 46 to the logic substrate 3, and a second wire 49 connecting the second terminal 47 to the logic substrate 3, and the logic substrate 3 includes a first connection wire 50 connecting the first wire 48 and the second wire 49 together.

In the foregoing configuration, the first terminal and the second terminal, which are identical nodes of the pixel circuit provided on the logic substrate, are connected together via the first connection wire, provided on the logic substrate. Accordingly, an empty space, when produced in the logic circuit stacked on the pixel circuit, can be effectively used for connection between the first terminal and second terminal of the pixel circuit. This can prevent a resistance that is excited on the wires while increasing wire flexibility to optimize a layout area.

The solid-state image pickup element IF according to an eighth aspect of the disclosure is preferably configured, in the seventh aspect, such that the pixel substrate 2 includes a first wire layer 27, such that the logic substrate 3 includes a second wire layer 28, such that the first terminal 46 and the second terminal 47 are not electrically connected together in the first wire layer 27, and such that the first terminal 46 and the second terminal 47 are electrically connected together in only the second wire layer 28.

The solid-state image pickup element 1A according to a ninth aspect of the disclosure is preferably configured, in the seventh or eighth aspect, such that the logic circuit 8 includes a pixel driving circuit 9 for driving the unit pixel 17, and a signal processing circuit 10 for processing a signal output from the pixel array 4, and such that the joint portion 5 further includes a third wire 52 connecting the first terminal 46 to the logic substrate 3, and a fourth wire 53 connecting the second terminal 47 to the logic substrate 3.

The solid-state image pickup element 1E to 1H according to a tenth aspect of the disclosure is preferably configured, in any one of the seventh to ninth aspects, such that the first terminal 46 is one of a power source terminal and a ground terminal, and such that the second terminal 47 is another one of the power source terminal and the ground terminal.

The solid-state image pickup element 1H according to an eleventh aspect of the disclosure is preferably configured, in any one of the seventh to tenth aspects, such that the pixel circuit (pixel reading circuit 45) has a third terminal 46H and a fourth terminal 47H that are other nodes identical to each other, such that the joint portion 5 includes a fifth wire 48H connecting the third terminal 46H to the logic substrate 3, and a sixth wire 49H connecting the fourth terminal 47H to the logic substrate 3, and such that the logic substrate 3 includes a third connection wire 50H connecting the fifth wire 48H and the sixth wire 49H together.

The solid-state image pickup element ID according to a twelfth aspect of the disclosure is preferably configured, in the eighth aspect, such that the second wire layer 28 is a multi-layer wire layer, such that the first connection wire 50 is formed in one or more layers of the multi-layer wire layer, and such that the first connection wire 50 has a structure including a plurality of the first connection wires 50 connected together while crisscrossing in a lattice manner.

An electronic device (camera 54) according to a thirteenth aspect of the disclosure includes the solid-state image pickup element 1, 1A to 1H according to any one of the first to twelfth aspects of the disclosure.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A solid-state image pickup element comprising:
a pixel substrate having a pixel array where a unit pixel including a photoelectric-conversion element is disposed in rows and columns;
a logic substrate having a logic circuit that relates to the pixel array, and stacked on the pixel substrate; and
a joint portion joined in such a manner that uppermost-layer wires of the respective pixel substrate and logic substrate face each other, to electrically connect the pixel substrate and the logic substrate together,
wherein the logic circuit has a first terminal and a second terminal that are nodes identical to each other,
the node of the first terminal and the node of the second terminal are nodes that are used for a circuit operation on only the logic substrate,
the joint portion includes
a first wire connecting the first terminal to the pixel substrate, and
a second wire connecting the second terminal to the pixel substrate, and
the pixel substrate includes a first connection wire connecting the first wire and the second wire together.

2. The solid-state image pickup element according to claim 1, wherein
the pixel substrate includes a first wire layer,
the logic substrate includes a second wire layer,
the first terminal and the second terminal are not electrically connected together in the second wire layer, and
the first terminal and the second terminal are electrically connected together in only the first wire layer.

3. The solid-state image pickup element according to claim 1, wherein
the logic circuit includes
a pixel driving circuit for driving the unit pixel, and
a signal processing circuit for processing a signal output from the pixel array, and
the joint portion further includes
a third wire connecting the first terminal to the pixel substrate, and
a fourth wire connecting the second terminal to the pixel substrate.

4. The solid-state image pickup element according to claim 1, wherein
the first terminal is one of a power source terminal and a ground terminal, and
the second terminal is another one of the power source terminal and the ground terminal.

5. The solid-state image pickup element according to claim 1, wherein
the logic circuit further has a third terminal and a fourth terminal that are other nodes identical to each other,
the joint portion further includes
a fifth wire connecting the third terminal to the pixel substrate, and
a sixth wire connecting the fourth terminal to the pixel substrate, and
the pixel substrate further includes a third connection wire connecting the fifth wire and the sixth wire together.

6. The solid-state image pickup element according to claim 2, wherein
the first wire layer is a multi-layer wire layer;
the first connection wire is formed in one or more layers of the multi-layer wire layer, and
the first connection wire has a structure comprising a plurality of the first connection wires connected together while crisscrossing in a lattice manner.

7. A solid-state image pickup element comprising:
a pixel substrate having a pixel array where a unit pixel including a photoelectric-conversion element is disposed in rows and columns, and a pixel circuit that relates to the pixel array;
a logic substrate having a logic circuit that relates to the pixel array, and stacked on the pixel substrate; and
a joint portion joined in such a manner that uppermost-layer wires of the respective pixel substrate and logic substrate face each other, to electrically connect the pixel substrate and the logic substrate together,
wherein the pixel circuit has a first terminal and a second terminal that are nodes identical to each other,
the node of the first terminal and the node of the second terminal are nodes that are used for a circuit operation on only the pixel substrate,
the joint portion includes
a first wire connecting the first terminal to the logic substrate, and
a second wire connecting the second terminal to the logic substrate, and
the logic substrate includes a first connection wire connecting the first wire and the second wire together.

8. The solid-state image pickup element according to claim 7, wherein
the pixel substrate includes a first wire layer,
the logic substrate includes a second wire layer,
the first terminal and the second terminal are not electrically connected together in the first wire layer, and
the first terminal and the second terminal are electrically connected together in only the second wire layer.

9. The solid-state image pickup element according to claim 7, wherein
the logic circuit includes
a pixel driving circuit for driving the unit pixel, and
a signal processing circuit for processing a signal output from the pixel array, and
the joint portion further includes
a third wire connecting the first terminal to the logic substrate, and
a fourth wire connecting the second terminal to the logic substrate.

10. The solid-state image pickup element according to claim 7, wherein
the first terminal is one of a power source terminal and a ground terminal, and
the second terminal is another one of the power source terminal and the ground terminal.

11. The solid-state image pickup element according to claim 7, wherein
the pixel circuit has a third terminal and a fourth terminal that are other nodes identical to each other,
the joint portion includes
a fifth wire connecting the third terminal to the logic substrate, and
a sixth wire connecting the fourth terminal to the logic substrate, and
the logic substrate includes a third connection wire connecting the fifth wire and the sixth wire together.

12. The solid-state image pickup element according to claim 8, wherein
the second wire layer is a multi-layer wire layer,
the first connection wire is formed in one or more layers of the multi-layer wire layer, and
the first connection wire has a structure comprising a plurality of the first connection wires connected together while crisscrossing in a lattice manner.

13. An electronic device comprising the solid-state image pickup element according to claim 1.
